(19) United States
(12) Patent Application Publication
(10) Pub. No.: US 2002/0011631 A1
(43) Pub. Date: Jan. 31, 2002

(54) SELF-ALIGNED METAL SILICIDE

(76) Inventor: GARY HONG, HSINCHU (TW)

Correspondence Address: J C PATENTS INC, 4 VENTURE, SUITE 250, IRVINE, CA, 92618, US

(21) Appl. No.: 09/293,419

(22) Filed: Apr. 16, 1999

(30) Foreign Application Priority Data
Mar. 19, 1999 (TW) 88104320

(51) Int. Cl. H01L 29/76; H01L 29/94; H01L 31/062; H01L 31/113; H01L 31/119

(52) U.S. Cl. 257/382

(57) ABSTRACT

A structure of self-aligned metal silicide. A gate oxide layer is formed on a substrate. A gate with a sidewall and a top surface thereof is formed on the gate oxide layer. A first silicidation step is performed to form a first metal silicide layer on both the sidewall and the top surface. A spacer is formed to cover the first metal silicide layer on the sidewall of the gate. An ion implantation is performed to form a source/drain region in the substrate with the gate as a mask. A second silicidation step is formed to form a second metal silicide layer on the source/drain region.

### CROSS-REFERENCE TO RELATED APPLICATION

This application claims the priority benefit of Taiwan application Ser. no. 88104320, filed Mar. 19, 1999, the full disclosure of which is incorporated herein by reference.

### BACKGROUND OF THE INVENTION

1. Field of the Invention

The invention relates to a structure of a semiconductor device. More particularly, the invention relates to a structure of a self-aligned metal silicide (salicide) layer.

2. Description of the Related Art

The technique of fabricating a salicide layer has been widely applied to processes of fabricating a very large scale integration (VLSI) with a line width smaller than 0.5 μm. By implementing this technique, a sheet resistance of source/drain regions of a metal-oxide semiconductor (MOS) can be reduce, and integrity of shallow junctions between a metal layer and the MOS can be maintained.

FIG. 1 shows a cross sectional view of a MOS device comprising a salicide layer. A MOS device comprising a polysilicon gate 12, a source/drain region 14, a lightly doped drain (LDD) region 14a and a spacer 16 on a sidewall of the gate 12 is formed on the substrate 10. A metal layer is deposited on the MOS device followed by a thermal process. A part of the metal layer reacts with the gate 12 and the source/drain region 14 to produce a metal silicide layer 18 on the gate 12 and the source/drain region 14. The metal layer over positions other than the source/drain region 14 and the gate 12, that is, the unreacted metal layer is then removed by wet etching.

As the integration of a chip increases, the surface area available for forming a device is decreased. It is known that resistance of a material is proportional to the length thereof, and inversely proportional to the cross section area thereof. The relationship between the resistance R, the length L and the cross section area A is “R∝L/A”. Thus, the metal silicide layer fabricated by the conventional method has an increased resistance since the cross sectional area is reduced, and therefore, fail to enhance the conducting performance of the gate and the source/drain region as required. The is even more obvious while the gate dimension is lowered to under 0.2 μm.

### SUMMARY OF THE INVENTION

Accordingly, the invention provides a method of fabricating a self-aligned metal silicide layer. The method can be applied to a fabrication process with a gate dimension less than 0.2 μm, and the resultant effectively enhance the conducting performance of the gate. Furthermore, the salicide layers are formed on a gate and a source/drain region in different step, so that the salicide layers formed on different regions can be selected from the same or different material to optimize the device performance.

The invention provides a structure of a self-aligned metal silicide layer. A substrate comprises a gate and a source/drain region. The gate has a sidewall and a top surface. Both of the sidewall and the top surface are covered with a first silicide layer. The gate further comprises a spacer on the first silicide layer which covers the sidewall of the gate. The source/drain region is covered by a second silicide layer.

From the above method, a metal silicide layer is formed to cover both the sidewall and the top surface. Therefore, even when the gate dimension, for example, the length or the width of the top surface is reduced, the metal silicide is formed covering the whole surface of that gate, including the top surface and the sidewall. Therefore, as the resistance of the gate is reduced with the increasing contact area. The conducting performance of the gate can thus be greatly improved.

It is to be understood that both the foregoing general description and the following detailed description are exemplary and explanatory only and are not restrictive of the invention, as claimed.

### BRIEF DESCRIPTION OF THE DRAWINGS

FIG. 1 shows a cross sectional view of a self-aligned metal silicide layer on a MOS device formed by a conventional method; and

FIG. 2A to FIG. 2F are cross sectional views showing a fabricating process of a self-aligned method silicide layer according to a preferred embodiment of the invention.

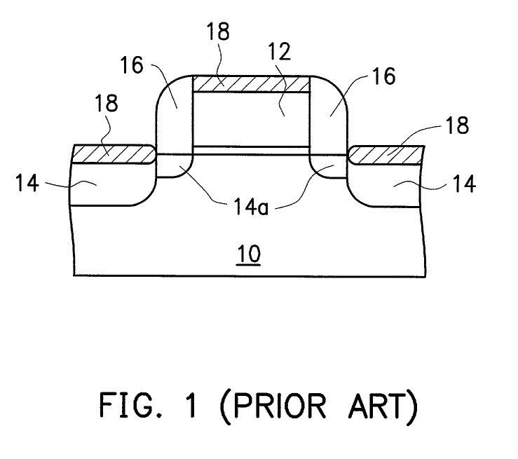

### DESCRIPTION OF THE PREFERRED EMBODIMENTS

In the invention, a two-step silicidation process is employed. A first silicide layer is formed to cover a top surface and a sidewall of a gate, followed by the formation of a spacer on the first silicide layer covering the sidewall of the gate. A source/drain region is formed, and a second silicidation process is performed to form a second silicide layer on the source/drain region. The first silicide layer does not only cover the top surface of the gate, but also covering the sidewall of thereof. Thus, the cross sectional area is greatly increased to effectively reduce the resistance of the gate. Furthermore, since the first silicide layer and the second silicide layer are formed in different step, the material of the first and the second silicide layers can thus be selected independently with each other. For example, the first silicide layer can be made cobalt silicide (CoSi₂) to obtain a stable resistance, while the second silicide layer can be made of titanium silicide (TiSi₂) to lower device leakage.

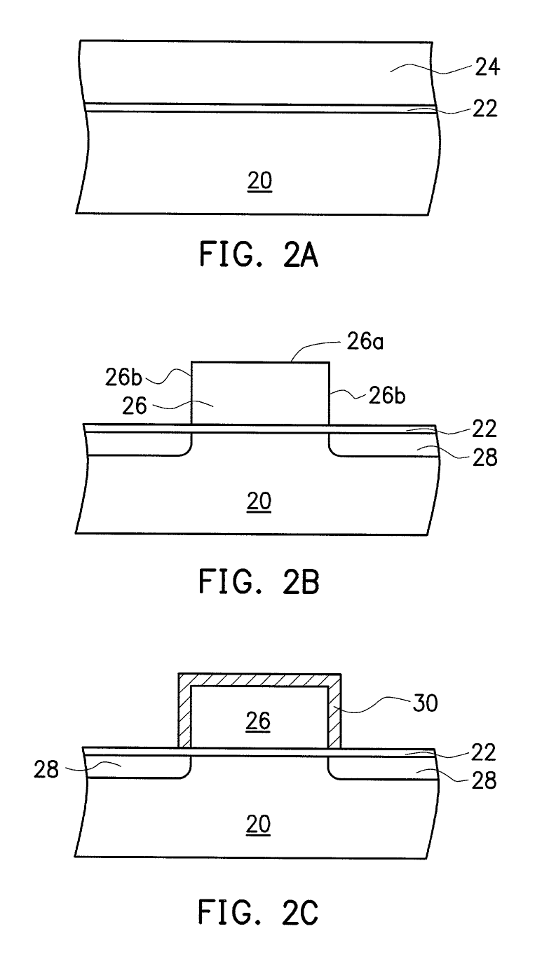

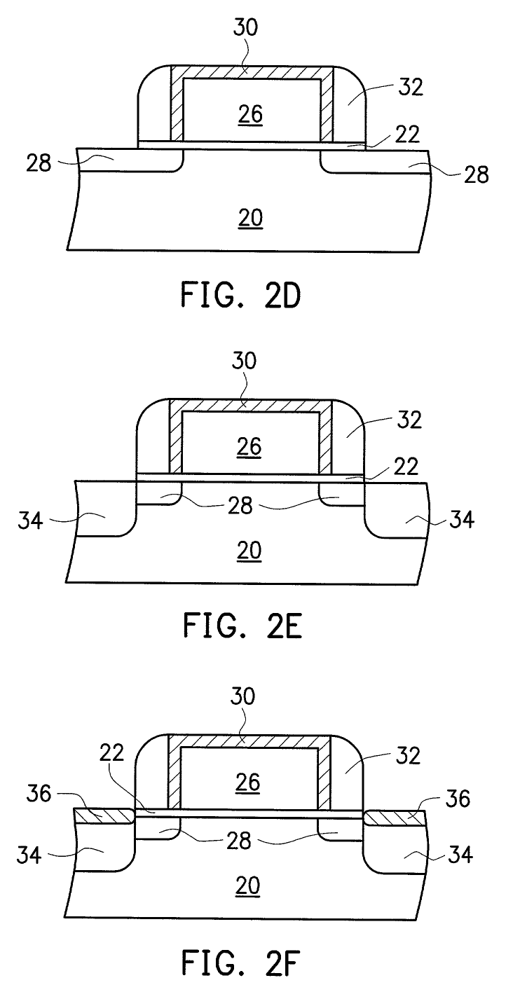

FIG. 2A to FIG. 2F illustrate a preferred embodiment of a fabrication process for forming a self-aligned silicide layer.

In FIG. 2A, a substrate 20 is provided. A gate oxide layer 22 is formed on the substrate 20, for example, by thermal oxidation. A conductive layer 24, for example, a doped polysilicon layer formed by chemical vapor deposition (CVD), is formed on the gate oxide layer 22.

In FIG. 2B, a photolithography and etching step is performed. The conductive layer 24 is patterned to form a gate 26. The exposed surfaces of that gate 26 comprise a top surface 26a and a sidewall 26b. Using the gate 26 as a mask, an ion implantation is performed to the substrate 20 to form a lightly doped drain region (LLD) 28.

In FIG. 2C, a first silicidation step is performed. A metal layer (not shown), for example, a titanium layer, a cobalt layer, or other refractory metal layer, is formed on the gate oxide layer 22 and the gate 26. A thermal process is performed to enable the metal layer to react with the gate 26, while the substrate 20 is covered by a gate oxide layer 22 which prevents the reaction between the substrate 20 and the metal layer. Consequently, a metal silicide layer 30, for example, a titanium silicide or a cobalt silicide layer with a thickness of about 200 to 1000 Å is formed to cover the exposed surfaces, including the top surface 26a and the sidewall 26b of the gate 26. After the reaction, the unreated metal layer is removed, for example, using selective wet etching. That is, in this embodiment, the metal layer covering the lightly doped drain region 28 is not reacted and is removed to expose the gate oxide layer 22. A post annealing step is then performed.

In FIG. 2D, a spacer 32 is formed on the silicide layer 30 covering the sidewall 26b of the gate 26. For example, a silicon nitride layer is formed over the substrate 20. The silicon nitride layer is etched anisotropically, and the gate oxide layer 22 is removed to expose the substrate 20. The etching step of the silicon nitride layer to form the spacer 32 and the removing step of the gate oxide layer 22 can be performed as a single step by using an etchant with a proper etching selectivity.

In FIG. 2E, using the gate 26 and the spacer 32 as masks, the substrate 20 is implanted with ions to form a source/drain region 34. The ions implanted to form the source/drain region 34 have a heavier concentration compared to that of the lightly doped drain region 28.

In FIG. 2F, a second step of silicidation is performed. A metal layer (not shown), for example, a titanium layer, a cobalt layer, or other refractory metal layers with a thickness of about 200 to 1000 Å, is formed to cover the source/drain region 34 over the substrate 20. A thermal process is performed to enable the metal layer to react with the source/drain region 34 to form a metal silicide layer 36, for example, a titanium silicide or a cobalt silicide layer. After the reaction, the unreated metal layer is removed, for example, using selective wet etching, followed by a post annealing process. That is, in this embodiment, the metal layer covering the positions other than the source/drain region 34 is not reacted and is removed.

By the above method, a metal-oxide semiconductor (MOS) device is formed on a substrate with two salicide layers formed in two different process steps. The silicide layers comprises a first silicide layer formed on a gate of the device and a second silicide layer on the source/drain region. These two silicide layers can be made of the same material or different materials in order to optimize the device performance. Furthermore, the thickness of these two silicide layers can be the same or different from each other according to a specific requirements. For example, by selecting titanium silicide layer to form the silicide layer on the gate, a stable resistance is resulted. On the other hand, by selecting cobalt silicide layer as the silicide layer on the source/drain region, a device leakage can be avoided.

Other embodiment of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A structure of a self-aligned silicide layer, comprising:
a substrate;
a gate, having a sidewall and a top surface;
a first silicide layer, covering the sidewall and the top surface of the gate;
a spacer, on the first silicide layer covering the sidewall;
a source/drain region, along the gate in the substrate; and
a second silicide layer, on the source/drain region.

2. The structure according to claim 1, wherein the source/drain region comprises further a lightly doped drain region.

3. The structure according to claim 1, wherein the gate comprising a doped polysilicon layer.

4. The structure according to claim 1, wherein the first silicide layer comprises a titanium silicide layer.

5. The structure according to claim 1, wherein the first silicide layer comprises a cobalt silicide layer.

6. The structure according to claim 1, wherein the first silicide layer has a thickness of about 200 to 1000 Å.

7. The structure according to claim 1, wherein the second silicide layer comprises a titanium silicide layer.

8. The structure according to claim 1, wherein the second silicide layer comprises a cobalt silicide layer.

9. The structure according to claim 1, wherein the second silicide layer has a thickness of about 200 to 1000 Å.

10. The structure according to claim 1, wherein the first silicide layer is a cobalt silicide layer and the second silicide layer is a titanium silicide layer.

12. The structure according to claim 1, comprising further a gate oxide layer between the gate and the substrate, and the spacer and the substrate.

13. A metal-oxide semiconductor device, comprising:
a substrate;
a gate on the substrate, the gate having a sidewall and a top surface;
a spacer over the sidewall;
a gate oxide layer on the substrate, covered by the gate and the spacer;
a first self-aligned silicide layer, between the sidewall and the spacer;
a source/drain region along the sidewall in the substrate; and
a second self-aligned silicide layer, on the source/drain region.

14. The device according to claim 13, wherein the first silicide layer is made of a material different from that of the second silicide layer.

15. The device according to claim 13, wherien the first silicide layer is made of cobalt silicide, while the second silicide layer is made of titanium silicide.

16. The device according to claim 13, wherein the first silicide layer and the second silicide layer are made of a same material.

17. The device according to claim 13, wherein the first silicide layer is formed before formation of the second silicide layer.
